(19) United States
(12) Patent Application Publication
(10) Pub. No.: US 2010/0078814 A1
(43) Pub. Date: Apr. 1, 2010

(54) SYSTEM AND METHOD FOR USING POROUS LOW DIELECTRIC FILMS

(76) Inventors: Alok Nandini ROY, San Jose, CA (US); Zubin P. PATEL, San Jose, CA (US); Shenqing FANG, Fremont, CA (US)

Correspondence Address: SPANSION LLC C/O MURABITO , HAO & BARNES LLP, TWO NORTH MARKET STREET, THRID FLOOR, SAN JOSE, CA, 95113, US

(21) Appl. No.: 12/240,627

(22) Filed: Sep. 29, 2008

(51) Int. Cl. H01L 23/52; H01L 21/4763

(52) U.S. Cl. 257/741; 438/687; 257/773; 257/E23.141; 257/E21.495

(57) ABSTRACT

A system and method for manufacturing a semiconductor device including a low dielectric constant porous material layer. Ions are implanted into the low dielectric constant porous material layer which thereby provides the porous material layer with sufficient mechanical strength for withstanding semiconductor manufacturing processes. The ions implanted in the porous material layer further facilitate disposition of a conductive layer on the porous material layer.

### FIELD OF THE INVENTION

The present invention relates to the field of semiconductors. More particularly, the present invention relates to a system and method for utilizing porous films as Inter Layer Dielectric materials.

### BACKGROUND OF THE INVENTION

Electronic systems and circuits have made a significant contribution towards the advancement of modern society and are utilized in a number of applications to achieve advantageous results. Electronic technologies such as digital computers, calculators, audio devices, video equipment, and telephone systems have facilitated increased productivity and reduced costs in analyzing and communicating data, ideas and trends in most areas of business, science, education and entertainment. Correspondingly, as technology has advanced, electronic technologies are increasingly shrinking in size. As electronic components shrink, electrical interference and other negative effects on electrical components, such as wires, have an increasingly large impact. The tiny widths and close proximity of adjacent lines introduces resistance and capacitance delays that can hinder chip performance.

One particular such problem is that the RC (resistive-capacitive) delay on interconnects increases as devices are made smaller. The capacitance may be expressed by the equation:

$$C = K {ɛ}_{0} \frac{A}{D}$$

Where A is the area, D is the thickness, K is the dielectric constant of the material, and ∈₀ is the permittivity of free space. The area (A) and thickness (D) are governed by the microelectronic chip size.

Accordingly, conventional solutions have been focused on using materials which have a low dielectric constant, such as, porous materials. Unfortunately, porous materials are not able to withstand the mechanical stresses during semiconductor manufacturing, such as, the Chemical Mechanical Polish (CMP) step in damascene processes.

Additionally, the porous nature of the material makes copper deposition problematic as the copper diffuses into the pores of the porous material. One such solution to this problem has been to put an additional layer on top of the porous material. The additional layer provides a sufficient barrier to prevent copper from diffusing into the pores, however, the additional layer increases the dielectric constant. Further, the additional layer requires an additional step in the manufacturing process, as well as, increasing the thickness.

Accordingly, what is needed is a way to manufacture a semiconductor using a material with an appropriate dielectric constant with sufficient mechanical strength for further semiconductor processing and manufacture.

### SUMMARY OF THE INVENTION

A system and method for manufacturing a semiconductor device including a low dielectric constant porous material layer. Ions are implanted into the low dielectric constant porous material layer which thereby provides the porous material layer with sufficient mechanical strength for withstanding semiconductor manufacturing processes. The ions implanted in the porous material layer further facilitate disposition of a conductive layer on the porous material layer.

The system and method of the present invention facilitates use of low dielectric constant porous materials in semiconductor devices. Ions implanted in the porous material provide mechanical strength to the porous material to withstand subsequent semiconductor manufacturing steps or processes with minimal change in chemical properties of the porous material. The implanted ions further facilitate adhesion of a conductive material layer (e.g., copper) and prevent diffusion of the conductive layer into the pores of the porous material. In addition, the implanted ions results in the porous material layer being hydrophobic. Moreover, the implanted ions avoid increases in thickness caused by a capping layer and thereby facilitate reduced fabrication times and reduce costs. The ions provide the aforementioned advantageous properties with relatively small change in to the dielectric constant of the porous material.

### BRIEF DESCRIPTION OF THE DRAWINGS

FIG. 1 is a flowchart of an exemplary method for manufacturing a semiconductor device in accordance with an embodiment of the present invention.

FIG. 2 is a cross section of an exemplary semiconductor device during manufacturing in accordance with an embodiment of the present invention.

FIG. 3 is a cross section of an exemplary semiconductor device during manufacturing in accordance with an embodiment of the present invention.

FIG. 4 is a cross section of an exemplary semiconductor device in accordance with an embodiment of the present invention.

### DETAILED DESCRIPTION OF THE INVENTION

Reference will now be made in detail to the preferred embodiments of the invention, a semiconductor isolation material deposition system and method, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one ordinarily skilled in the art that the present invention may be practiced without these specific details. In other instances, well known methods, procedures, components, and circuits have not been described in detail as not to unnecessarily obscure aspects of the current invention.

Some portions of the detailed descriptions which follow are presented in terms of procedures, logic blocks, processing, and other symbolic representations of operations on data bits within a computer memory. These descriptions and representations are the means generally used by those skilled in data processing arts to effectively convey the substance of their work to others skilled in the art. A procedure, logic block, process, etc., is here, and generally, conceived to be a self-consistent sequence of steps or instructions leading to a desired result. The steps include physical manipulations of physical quantities. Usually, though not necessarily, these quantities take the form of electrical, magnetic, optical, or quantum signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are associated with the appropriate physical quantities and are merely convenient labels applied to these quantities. Unless specifically stated otherwise as apparent from the following discussions, it is appreciated that throughout the present application, discussions utilizing terms such as “processing”, “computing”, “calculating”, “determining”, “displaying” or the like, refer to the action and processes of a computer system, or similar processing device (e.g., an electrical, optical, or quantum, computing device), that manipulates and transforms data represented as physical (e.g., electronic) quantities. The terms refer to actions and processes of the processing devices that manipulate or transform physical quantities within a computer system's component (e.g., registers, memories, other such information storage, transmission or display devices, etc.) into other data similarly represented as physical quantities within other components.

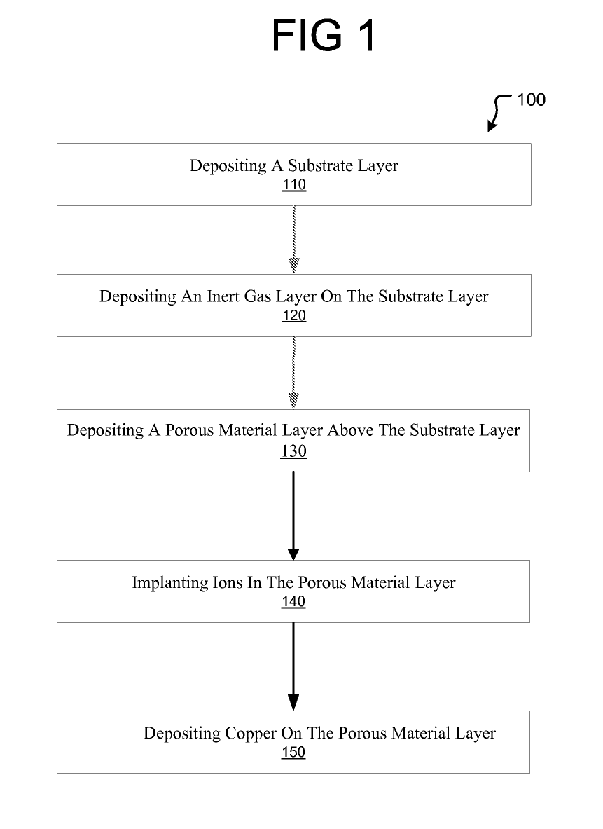

FIG. 1 is a flowchart of an exemplary method 100 for manufacturing a semiconductor device in accordance with an embodiment of the present invention. With reference to FIG. 1, flowchart 100 illustrates example blocks used by various embodiments of the present technology. It is appreciated that the blocks of flowchart 100 may be performed in an order different than presented, and that not all of the blocks in flowchart 100 may be performed. Exemplary method 100 may be used to manufacture a portion of a memory device (e.g., semiconductor device 200). It is appreciated that flowchart 100 may be carried out by a semiconductor manufacturing device or fabrication device. It is further appreciated that method 100 can be used for multiple layers. Embodiments of the present invention can be used in semiconductor manufacturing processes from 90 nm to 32 nm and beyond.

At block 110, a semiconductor substrate layer is deposited. At block 120, an inert gas layer is deposited on the substrate layer. In one embodiment, the inert gas layer comprises Argon.

At block 130, a porous material layer or film is deposited above the substrate layer. The porous material may be selected based on a relatively low dielectric constant (e.g., 1.5-2.5). The porous material may be a variety of materials including, but not limited to, an oxide material (e.g., SiO2), polyarylene ether, Polytetrafluoroethylene (PTFE), methyl silsequioxane (MSSQ), hydrogen silsequioxane (HSSQ), Chemat porous films, Parylene, templated silica, or SiLK by Dow Chemical Company of Midland Mich.

At block 140, ions are implanted in the porous material layer. It is appreciated that the dose, energy, and type of ions can be varied or selected according to the application being used or semiconductor device being made. In one embodiment, the dose, energy, and ions use may be selected based on amount of change of the dielectric constant, strength of the porous material layer after implantation, level of diffusion into the pores of the porous material, the hydrophobic nature of the resulting implanted material, thickness, and adhesiveness. To the extent possible the dose, energy, and type of ions are selected so the dielectric constant of the porous material layer (with implanted ions) remains substantially unchanged after implantation of the ions. It is further appreciated that implanting may beneficially facilitate surface cleaning of the porous material layer (e.g., removal of organic contamination from the surface).

The ions and associated implantation properties may further be selected so as to harden the surface of the porous material layer. For example, the ions may be selected to provide sufficient strength to the porous material layer to withstand mechanical stresses of semiconductor manufacturing (e.g., Chemical Mechanical Polish (CMP) step in damascene processes). The implantation may thus be performed so as to balance between hardening the porous material layer and changing the dielectric constant of the porous layer material with implanted ions.

The ions may further be selected based on the hydrophobic nature of the resulting implanted surface of the porous material layer. For example, pores of the porous material layer may normally absorb moisture and the ion implantation results in a surface chemical modification making the porous material layer (or films) hydrophobic.

In one exemplarily embodiment, multiple implants may be done to the extent necessary to achieve the desired properties while avoiding significant changes in dielectric constant. Correspondingly, the integrity of the porous material layer may be checked after each ion implantation. The ions may be implanted by indenting with a needle on the surface of the porous material layer.

In one embodiment, the ions are noble gas ions and may be selected from the group consisting of Argon, Helium, Xenon, Neon, and Helium. In addition, other ions may be used including, but not limited to Nitrogen and Carbon. In one exemplary embodiment, a porous film of 0.5 to 1 μm is implanted with ions via a dose of 2×10¹⁵ or 1×10¹⁶ Ar ions/cm², with energy of 50, 75, 100 and 150 keV, and a thermal treatment of annealed in inert ambient at 450° C. for 1 hour. In another exemplary embodiment, Argon ions are implanted with an energy of 20 keV, a dose of 1×10¹⁶ ions/cm², and a thermal treatment in an inert ambient environment for 1 hour.

Embodiments may further be used in Silicon on Glass (SOG) applications. The role of metastable Ar (Ar*) ions may play an important role in improving the SOG film and further the SOG film may be more relaxed by the energy released from the conversion of Ar* to Ar.

At block 150, copper is deposited on the porous material layer. It is appreciated that any conductive material may be used. The ions implanted within the porous material layer prevents diffusion of the copper into the pores of porous material layer. For example, the modified surface of the porous material layer prevents chemical penetration of gases into the low dielectric constant (K) porous material during chemical vapor deposition (CVD) (e.g., Cu deposition). In one exemplary embodiment, NAND back end of line (BEOL) interconnections can be made with materials having less than a 2.5 dielectric constant to insulate copper lines or wires.

The ions implanted further facilitate adhesion of the copper to the porous material layer. Ion implantation results in increased adhesive properties so conductive lines (e.g., copper lines or wires) adhere to the surface (e.g., able to pass the scotch tape test). For example, the copper may adhere better because of the increased surface area of the porous material. It is appreciated that embodiments may facilitate adhesion of other metals including, but not limited to, Ta, TaN, Ti, and TiN. It is further appreciated that embodiments may provide sufficient adhesive properties with or without thermal treatment after the ion implantation. In one exemplary embodiment, the implanted low dielectric constant materials are shown to be efficient solutions for high quality inter layer dielectric (ILD) films.

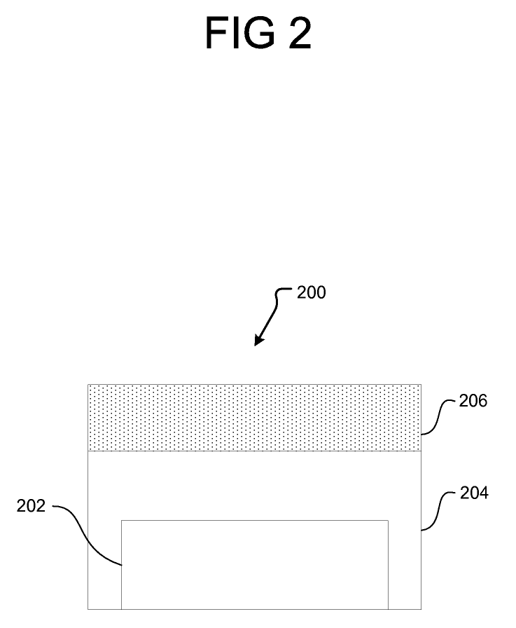

FIG. 2-4 illustrate cross sections of an exemplary semiconductor device (e.g., memory device) during various stages of manufacture (e.g., method 100). It is appreciated that a semiconductor device may include additional or not all of the components, layers, films, or materials described herein.

FIG. 2 is a cross section of an exemplary semiconductor device during manufacturing in accordance with an embodiment of the present invention. Semiconductor device 200 includes substrate layer 202, inert gas layer 204, and porous material layer 206.

In one embodiment, the inert gas layer 204 is deposited on substrate layer 202 and porous material layer 206 is deposited on inert gas layer 204. Inert gas layer 204 may include Argon. The material of porous material layer 206 may be selected based on having a relatively low dielectric constant of 1.5-2.5 and may be suited for manufacturing of 90 mm or less semiconductor device.

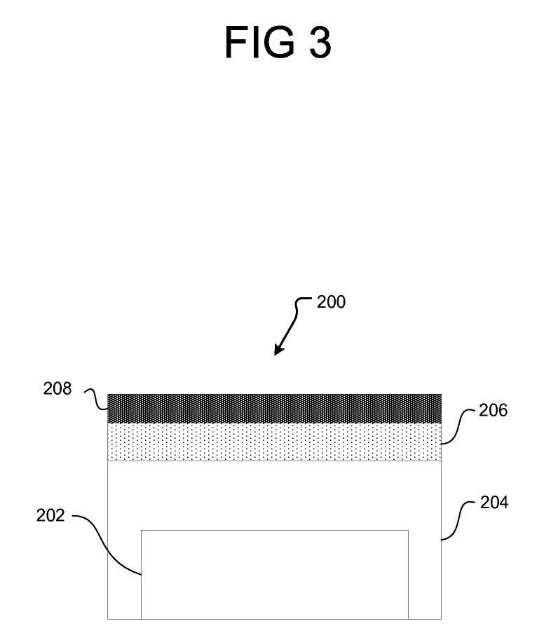

FIG. 3 is a cross section of an exemplary semiconductor device during manufacturing in accordance with an embodiment of the present invention. FIG. 3 shows substantially the semiconductor device of FIG. 2 with plurality of ions 208 implanted into porous material layer 206. In one embodiment, plurality of ions 208 is implanted substantially into a top or upper portion of porous material layer 206.

As described herein the plurality of ion 208 may be selected and implanted based on a plurality of properties of the resulting implanted layer including, but not limited to, strength, hydrophobic nature, adhesive properties, and diffusion of subsequent layers or films into the pores of porous material layer 206.

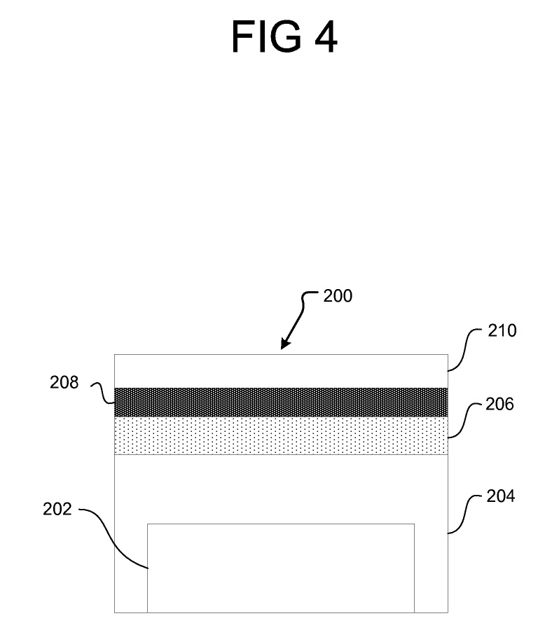

FIG. 4 is a cross section of an exemplary semiconductor device in accordance with one embodiment of the present invention. Semiconductor device 200 includes substrate layer 202, porous material layer 206, plurality of ions 208, and copper layer 210. FIG. 4 shows substantially the semiconductor device of FIG. 3 with copper layer 210 deposited substantially on the top portion of porous material layer 206 including plurality of ions 208. It is noted that in one embodiment, plurality of ions 208 may be implanted substantially in a top portion of porous material layer 206. It is appreciated that plurality of ions 208 may be implanted in a variety of portions of porous material layer 206.

Plurality of ions 208 prevents diffusion of copper layer 210 into the pores of porous material layer 206. Further, the implantation of plurality of ions 208 facilitates adhesion of copper layer 210 to porous material layer 206. In one embodiment, plurality of ions 208 are a noble gas (e.g., Argon, Helium, and Xenon). The dielectric constant of porous material layer remains substantially unchanged after implantation of plurality of ions 208.

The implantation of plurality of ions 208 provides sufficient strength to porous material layer 206 to withstand mechanical stresses of subsequent semiconductor manufacturing processes (e.g., Chemical Mechanical Polish). Implantation of plurality of ions 208 further results in the implanted portion of porous material layer 206 being advantageously hydrophobic as described herein.

In one embodiment, semiconductor device 200 may be a variety of devices including, but not limited to, gates (e.g., NAND gates) or a memory device (e.g., NAND based flash). A memory device in accordance with an embodiment of the present invention may include a semiconductor substrate (e.g., substrate layer 202), a plurality of wires (e.g., copper layer 210) disposed above the semiconductor substrate, and a porous material layer (e.g., porous material layer 206) disposed between the semiconductor layer and the plurality of wires. The porous material layer of an exemplary memory device, in accordance with an embodiment, includes a plurality of ions which fill a portion of the porous material layer.

The plurality of ions facilitates adhesion of the plurality of wires to the porous material layer. Further, the plurality of ions advantageously allow use of the porous material layer without requiring an increase in thickness below the plurality of wires (e.g., an additional layer or capping layer). Thus, embodiments of the present invention provide a solution of zero thickness or no increase in thickness.

Thus, a system and method of the present invention facilitates use of low dielectric constant porous materials in semiconductor devices. Ions implanted in the porous material provide mechanical strength to the porous material to withstand subsequent semiconductor manufacturing steps or processes with minimal change in chemical properties of the porous material. The implanted ions further facilitate adhesion of a conductive material layer (e.g., copper) and prevent diffusion of the conductive layer into the pores of the porous material. In addition, the implanted ions results in the porous material layer being hydrophobic. Moreover, the implanted ions avoid increases in thickness caused by a capping layer and thereby facilitate reduced fabrication times and reduce costs. The ions provide the aforementioned advantageous properties with relatively small change in to the dielectric constant of the porous material.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A semiconductor device comprising:
a substrate layer;
a porous material layer, wherein said porous material layer is deposited above said substrate layer; and
a plurality of ions implanted within a portion of said porous material layer, wherein said plurality of ions are implanted substantially in a top portion of said porous material layer; and
a copper layer, wherein said copper is deposited substantially on said top portion of said porous material layer comprising said plurality of ions.

2. The semiconductor device of claim 1 wherein said plurality of ions are a noble gas.

3. The semiconductor device of claim 2 wherein said plurality of ions are selected from the group consisting of Argon, Helium, and Xenon.

4. The semiconductor device of claim 1 wherein said plurality of ions provide sufficient strength to said porous material layer to withstand mechanical stresses of semiconductor manufacturing.

5. The semiconductor device of claim 1 wherein said plurality of ions are hydrophobic.

6. The semiconductor device of claim 1 wherein said plurality of ions facilitates adhesion of said copper layer to said porous material layer.

7. The semiconductor device of claim 1 wherein said plurality of ions prevents diffusion of said copper layer into said porous material layer.

8. The semiconductor device of claim 1 wherein the dielectric constant of said porous material layer remains substantially unchanged after implantation of said plurality of ions.

9. A method of manufacturing a semiconductor device, comprising:
depositing a substrate layer;
depositing a porous material layer above said substrate layer;
implanting ions in said porous material layer; and
depositing copper on said porous material layer.

10. The method of claim 9 further comprising:
depositing an inert gas layer on said substrate layer.

11. The method of claim 10 wherein said ions are a noble gas.

12. The method of claim 11 wherein said ions are selected from the group consisting of Argon, Helium, and Xenon.

13. The method of claim 9 wherein said ions provide sufficient strength to said porous material layer to withstand mechanical stresses of semiconductor manufacturing.

14. The method of claim 9 wherein said ions are hydrophobic.

15. The method of claim 9 wherein said ions facilitates adhesion of said copper to said porous material layer.

16. The method of claim 9 wherein said ions prevents diffusion of said copper into said porous material layer.

17. The method of claim 9 wherein the dielectric constant of said porous material layer remains substantially unchanged after implantation of said ions.

18. A memory device comprising:
a semiconductor substrate;
a plurality of wires disposed above said semiconductor substrate; and
a porous material layer disposed between said semiconductor substrate and said plurality of wires, wherein said porous material layer comprises a plurality of ions wherein said ions fill a portion of pores of said porous material layer.

19. The memory device of claim 18 wherein said plurality of ions allow use of said porous material layer without requiring an increase in thickness below said plurality of wires.

20. The memory device of claim 18 wherein said plurality of ions facilitates adhesion of said plurality of wires to said porous material layer.
